(19) United States
(12) Patent Application Publication
(10) Pub. No.: US 2011/0318020 A1
(43) Pub. Date: Dec. 29, 2011

(54) VERTICAL CAVITY SURFACE EMITTING LASER, VERTICAL-CAVITY-SURFACE-EMITTING-LASER DEVICE, OPTICAL TRANSMISSION APPARATUS, AND INFORMATION PROCESSING APPARATUS

(75) Inventors: Takashi KONDO, Kanagawa (JP); Kazutaka TAKEDA, Kanagawa (JP); Kazuyuki MATSUSHITA, Kanagawa (JP)

(73) Assignee: FUJI XEROX CO., LTD., TOKYO (JP)

(21) Appl. No.: 12/940,582

(22) Filed: Nov. 5, 2010

(30) Foreign Application Priority Data
Jun. 28, 2010 (JP) 2010-145940

(51) Int. Cl. H01S 5/183; H04B 10/04

(52) U.S. Cl. 398/182; 372/46.01; 372/46.013; G9B/7

(57) ABSTRACT

A vertical cavity surface emitting laser includes a substrate, a first semiconductor multilayer film reflector formed on the substrate, an active region formed on the first semiconductor multilayer film reflector, a second semiconductor multilayer film reflector formed on the active region, an electrode which is formed on the second semiconductor multilayer film reflector and in which a light emitting aperture is formed, a first substance that is composed of a material and that is formed in the light emitting aperture, and a second substance that is composed of a dielectric and that is formed on the first substance to cover one portion of the first substance. Light having an emission wavelength can pass through the material and dielectric. A reflectivity of a portion covered with the second substance is higher than a reflectivity of a portion that is not covered with the second substance.

### CROSS-REFERENCE TO RELATED APPLICATIONS

This application is based on and claims priority under 35 USC 119 from Japanese Patent Application No. 2010-145940 filed Jun. 28, 2010.

### BACKGROUND

(i) Technical Field

The present invention relates to a vertical cavity surface emitting laser, a vertical-cavity-surface-emitting-laser device, an optical transmission apparatus, and an information processing apparatus.

(ii) Related Art

Vertical cavity surface emitting lasers (VCSELs) are utilized as light sources of communication apparatuses or of image forming apparatuses. VCSELs that are utilized as such light sources are required to generate single (fundamental) transverse-mode oscillation, to have high optical power, and to have a long life. In VCSELs of a selective oxidation type, the oxidation aperture diameter of a current confinement layer is reduced to about 2 to 3 μm so that single transverse-mode oscillation is generated. When such a small oxidation aperture diameter is used, it is difficult to obtain an optical power of 3 mW or higher with stability.

### SUMMARY

According to a first aspect of the invention, there is provided a vertical cavity surface emitting laser including a substrate, a first semiconductor multilayer film reflector of a first conductivity type, an active region, a second semiconductor multilayer film reflector of a second conductivity type, an electrode, a first substance, and a second substance. The first semiconductor multilayer film reflector is formed on the substrate. The active region is formed on the first semiconductor multilayer film reflector. The second conductivity type is a conductivity type different from the first conductivity type, and the second semiconductor multilayer film reflector is formed on the active region. The electrode is formed on the second semiconductor multilayer film reflector, and, in the electrode, a light emitting aperture from which light is emitted is formed. The first substance is composed of a material which light having an emission wavelength is able to pass through, and is formed in the light emitting aperture of the electrode.

The second substance is composed of a dielectric which the light having the emission wavelength is able to pass through, and is formed on the first substance so as to cover one portion of the first substance. A thickness of the second substance is in a range between about ±10% of h_{di} that is obtained using Equation 1:

$${φ}_{air} = {sin}^{- 1} ( 2 π \frac{{h}_{di}}{λ} ) \\ {φ}_{di} = {sin}^{- 1} ( 2 π \frac{{h}_{di} {n}_{di}}{λ} ) \\ {φ}_{air} = {φ}_{di} \qquad ( 1 )$$

where h_{di} is a thickness of the dielectric, λ is an emission wavelength, n_{di} is a refractive index of the dielectric, φₐᵢᵣ is a phase of light that propagates through the air by a distance equal to the thickness h_{di}, and φ_{di} is a phase of light that propagates through the dielectric by a distance equal to the thickness h_{di}. A reflectivity of a portion that is covered with the second substance is higher than a reflectivity of a portion that is not covered with the second substance.

### BRIEF DESCRIPTION OF THE DRAWINGS

Exemplary embodiments of the present invention will be described in detail based on the following figures, wherein:

FIG. 1 includes a plan view of a VCSEL according to a first exemplary embodiment of the present invention and a cross-sectional view taken along the line A-A in the plan view;

FIG. 2 is a cross-sectional view in which a top portion of a mesa of the VCSEL illustrated in FIG. 1 is enlarged;

FIG. 3 includes a plan view of a top portion of a mesa of a VCSEL according to a second exemplary embodiment of the present invention and a cross-sectional view taken along the line B-B in the plan view;

FIG. 4 is a graph illustrating the relationships, in a case in which the phase difference between a phase of light that emanates from a region which is covered with a second insulating film and a phase of light that emanates from a region which is not covered with the second insulating film is adjusted, between the thickness of a first insulating film and the reflectivity difference between reflectivities of the regions that exist in a light emitting aperture;

FIG. 5 is a graph illustrating a far field pattern (FFP) in a case in which the thickness of the second insulating film is changed in the VCSEL according to the present exemplary embodiment;

FIGS. 6A and 6B are schematic cross-sectional views illustrating configurations of VCSEL devices in which the VCSEL according to the present exemplary embodiment and an optical member are implemented;

FIG. 7 is a diagram illustrating an example of a configuration of a light information processing apparatus in which the VCSEL according to the present exemplary embodiment is used as a light source; and

FIG. 8 is a schematic cross-sectional view illustrating a configuration of an optical transmission apparatus in which the VCSEL device illustrated in FIG. 6A is used.

### DETAILED DESCRIPTION

Next, exemplary embodiments of the present invention will be described with reference to the accompanying drawings. In the description given below, vertical cavity surface emitting lasers of a selective oxidation type are provided by way of examples, and referred to as “VCSELs”. It should be noted that, the scale of devices and apparatuses in the figures is enhanced in order to easily understand the features of the invention, and is not necessarily the same as the scale of the devices and apparatuses in reality.

### Exemplary Embodiments

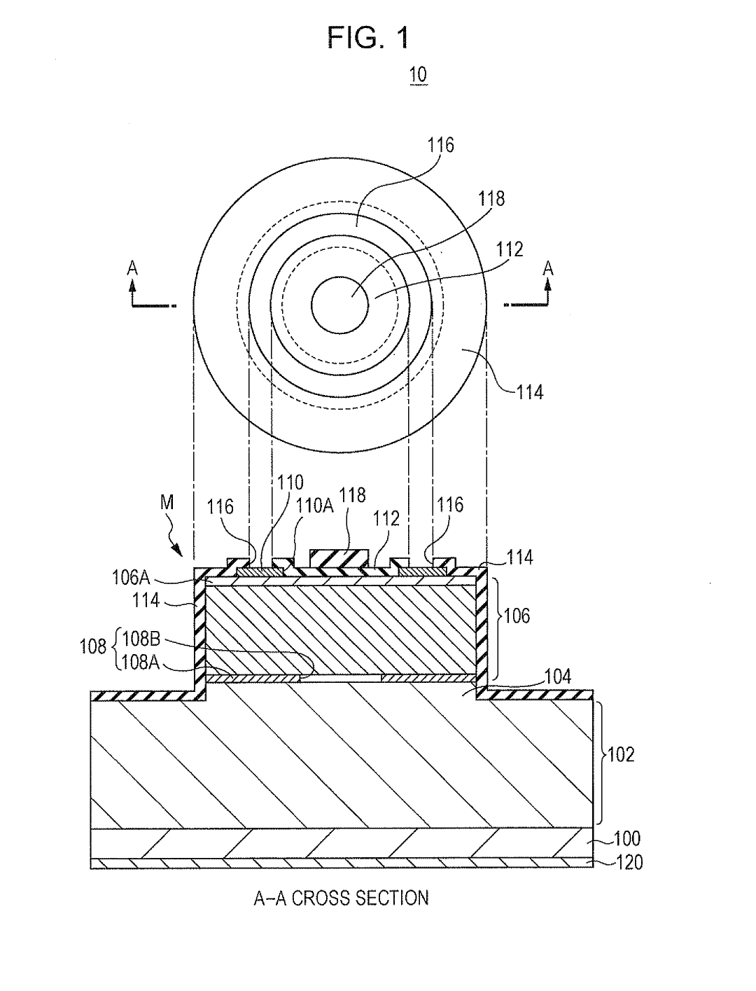

FIG. 1 is a schematic cross-sectional view of a VCSEL according to a first exemplary embodiment of the present invention. As illustrated in FIG. 1, a VCSEL 10 according to the present exemplary embodiment is configured so that an n-type lower distributed Bragg reflector (DBR) 102, an active region 104, and a p-type upper DBR 106 are stacked on an n-type GaAs substrate 100. In the lower DBR 102, AlGaAs layers having different aluminum contents are alternately stacked. The active region 104 is formed on the lower DBR 102, and includes a quantum well layer that is sandwiched between upper and lower spacer layers. The upper DBR 106 is formed on the active region 104, and, in the upper DBR 106, AlGaAs layers having different aluminum contents are alternately stacked.

The n-type lower DBR 102 is configured so that high-refractive-index layers and low-refractive-index layers having different aluminum contents are stacked. For example, multiple pairs of an Al_{0.9}Ga_{0.1}As layer and an Al_{0.3}Ga_{0.7}As layer are stacked. The thickness of each Al_{0.9}Ga_{0.1}As layer or Al_{0.3}Ga_{0.7}As layer is λ/4nᵣ (where λ is an emission wavelength and nᵣ is a refractive index of a medium). The Al_{0.9}Ga_{0.1}As layer and the Al_{0.3}Ga_{0.7}As layer are alternately stacked forty times. The carrier concentration of each of the Al_{0.9}Ga_{0.1}As layers and Al_{0.3}Ga_{0.7}As layers that have been doped with silicon which is an n-type impurity is, for example, 3×10¹⁸ cm⁻³.

The lower spacer layer of the active region 104 is an undoped Al_{0.6}Ga_{0.4}As layer. The quantum well layer includes an undoped Al_{0.11}Ga_{0.89}As quantum well layer and an undoped Al_{0.3}Ga_{0.7}As barrier layer. The upper spacer layer is an undoped Al_{0.6}Ga_{0.4}As layer.

The p-type upper DBR 106 is configured so that high-refractive-index layers and low-refractive-index layers having different aluminum contents are stacked. For example, multiple pairs of an Al_{0.9}Ga_{0.1}As layer and an Al_{0.3}Ga_{0.7}As layer are stacked. The thickness of each Al_{0.9}Ga_{0.1}As layer or Al_{0.3}Ga_{0.7}As layer is λ/4nᵣ. The Al_{0.9}Ga_{0.1}As layer and the Al_{0.3}Ga_{0.7}As layer are alternately stacked twenty-four times. The carrier concentration of each of the Al_{0.9}Ga_{0.1}As layers and Al_{0.3}Ga_{0.7}As layers that have been doped with carbon which is a p-type impurity is, for example, 3×10¹⁸ cm⁻³.

Furthermore, a contact layer 106A that is composed of p-type GaAs and that has a high impurity concentration is formed as the top layer of the upper DBR 106. A current confinement layer 108 that is composed of p-type AlAs is formed as the bottom layer of the upper DBR 106 or formed inside the upper DBR 106.

Semiconductor layers starting with the upper DBR 106 ending with the lower DBR 102 are etched, thereby forming a mesa (a columnar structure) M having a cylindrical shape on the substrate 100. The current confinement layer 108 is exposed on the side face of the mesa M, and includes an oxidized region 108A which is selectively oxidized from the side face, and an electrically conductive region (oxidized aperture) 108B around which the oxidized region 108A is formed. In a process of oxidizing the current confinement layer 108, an oxidation rate at which an AlAs layer is oxidized is higher than an oxidation rate at which an AlGaAs layer is oxidized. Oxidization progresses at a substantially fixed speed in a direction from the side face to the inside of the mesa M. Accordingly, the shape of a cross-section plane, which exists in a plane parallel to the principal plane of the substrate 100, of the electrically conductive region 108B is a circular shape in which the outer shape of the mesa M is reflected. The center of the electrically conductive region 108B coincides with the center of the mesa M in an axis direction, i.e., with an optical axis. The size of the diameter of the current confinement layer 108 may be a size of a diameter with which high-order transverse-mode oscillation can be generated, and may be, for example, 5 μm or larger for an emission wavelength band of 780 nm. Accordingly, a threshold current is reduced by the current confinement layer 108 included in the mesa M, and laser light having high optical power can be obtained.

A metallic ring-shaped p-side electrode 110 is formed as the top layer of the mesa M. The p-side electrode 110 is composed of, for example, a metallic material that is obtained by stacking Au, Ti/Au, or the like. The p-side electrode 110 is in ohmic contact with the contact layer 106A of the upper DBR 106. An opening having a circular shape is formed at the center of the p-side electrode 110, and the opening defines a light emitting aperture 110A from which light is emitted. The center of the light emitting aperture 110A coincides with the optical axis of the mesa M, and the diameter of the light emitting aperture 110A is larger than the diameter of the electrically conductive region 108B.

A first insulating film 112 having a circular shape is formed on the p-side electrode 110 so as to cover the light emitting aperture 110A. The first insulating film 112 is composed of a material that light having an emission wavelength can pass through, e.g., SiON. The outer diameter of the first insulating film 112 is larger than the diameter of the light emitting aperture 110A. The light emitting aperture 110A is completely covered with the first insulating film 112, and protected.

An interlayer insulating film 114 is formed so as to cover the bottom portion of the mesa M, the side portion of the mesa M, and the periphery of the top portion of the mesa M. The periphery of the interlayer insulating film 114 covers one portion of the p-side electrode 110. As a result, a ring-shaped contact hole 116 through which the p-side electrode 110 is exposed is formed between the interlayer insulating film 114 and the first insulating film 112. In a preferred example, because the same material that the interlayer insulating film 114 is composed of is used for the first insulating film 112, the first insulating film 112 is formed by the same process.

A second insulating film 118 that is composed of a dielectric material which light having an emission wavelength can pass through and that has a circular shape is formed on the first insulating film 112. An n-side electrode 120 is formed on the rear face of the substrate 100, and electrically connected to the lower DBR 102.

Here, the center of the second insulating film 118 coincides with the optical axis. The outer diameter of the second insulating film 118 is set to be equal to or smaller than the diameter of the electrically conductive region 108B. Preferably, a material for the second insulating film 118 is selected so that the second insulating film 118 has a refractive index nᵣ₂ which is higher than a refractive index nᵣ₁ of the first insulating film 112. For example, when the first insulating film 112 is composed of SiON, the second insulating film 118 is composed of SiN. A relationship nᵣ₂>nᵣ₁ is established, and the thickness of the first insulating film 112 and the thickness of the second insulating film 118 are appropriately selected, whereby, in the light emitting aperture 110A, a reflectivity R2 of a region that is covered with the second insulating film 118 can be made higher than a reflectivity R1 of a region that is not covered with the second insulating film 118. Accordingly, high-order transverse-mode oscillation can be reduced, and laser light generated by fundamental transverse-mode oscillation can be obtained. Note that a “circular shape” in the present specification conceptually includes not only a complete circle but also a circle having a radius that varies to some degree because of a variation in a production process and an ellipse.

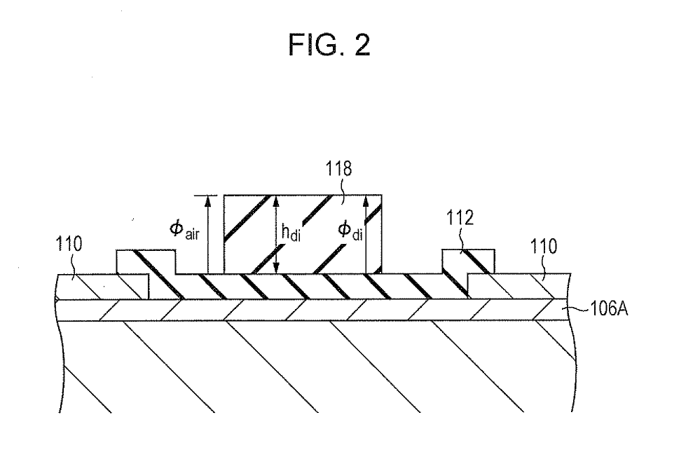

FIG. 2 is a cross sectional view in which the top portion of the mesa of the VCSEL 10 illustrated in FIG. 1 is enlarged. In FIG. 2, φₐᵢᵣ denotes a phase of laser light that emanates from the first insulating film 112 and that propagates through the air. φ_{di} denotes a phase of laser light that propagates through the second insulating film 118. h_{di} denotes the thickness of the second insulating film 118. In the present embodiment, the thickness h_{di} of the second insulating film 118 is selected so that the phase φₐᵢᵣ of laser light which emanates from the first insulating film 112 and which propagates through the air coincides with the phase φ_{di} of laser light which propagates through the second insulating film 118 and the phase difference between the phases is reduced. For this reason, the thickness of the second insulating film 118 is adjusted so that the thickness of the second insulating film 118 is in the range between about ±10% of the thickness h_{di} which is obtained using Equation 1 given below. Accordingly, in the light emitting aperture 110A, the phase difference between the phase of light that emanates from the region which is covered with the second insulating film 118 and the phase of light that emanates from the region which is not covered with the second insulating film 118 is reduced, whereby an FFP that is obtained using laser light generated by fundamental transverse-mode oscillation can be made to indicate a Gaussian distribution (normal distribution).

$${φ}_{air} = {sin}^{- 1} ( 2 π \frac{{h}_{di}}{λ} ) \\ {φ}_{di} = {sin}^{- 1} ( 2 π \frac{{h}_{di} {n}_{di}}{λ} ) \\ {φ}_{air} = {φ}_{di} \qquad ( 1 )$$

In Equation 1, h_{di} is a thickness of the dielectric, λ is an emission wavelength, n_{di} is a refractive index of the dielectric, φₐᵢᵣ is a phase of light that propagates through the air by a distance equal to the thickness h_{di}, and φ_{di} denotes a phase of light that propagates through the dielectric by a distance equal to the thickness h_{di}.

Supposing that the emission wavelength of the VCSEL 10 is 780 nm and the second insulating film 118 is composed of SiN, the refractive index n_{di} (=nᵣ₂) is 1.92. In this case, the thickness h_{di} of the second insulating film 118 that is obtained using Equation 1 is 848 nm. However, 848 nm is a thickness in a case in which the phase φₐᵢᵣ and the phase φ_{di} first coincide with each other. A thickness that is obtained by adding an integral multiple of 2λ (one wavelength) to 848 nm also satisfies Equation 1.

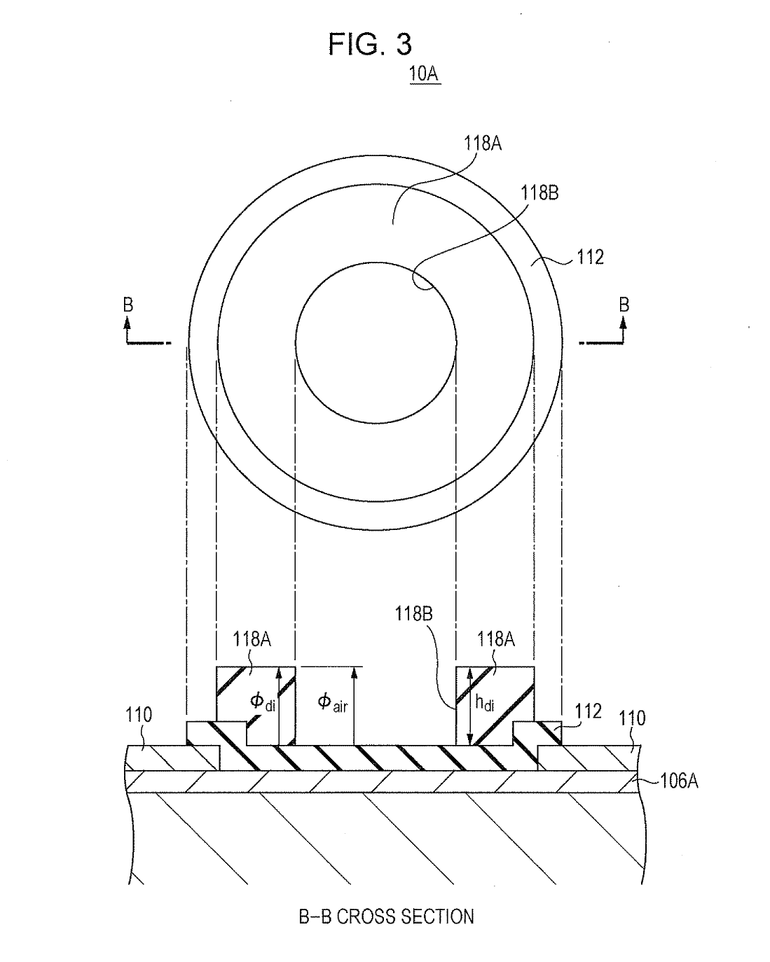

Next, a second exemplary embodiment of the present invention will be described. FIG. 3 includes a plan view of a top portion of a mesa of a VCSEL 10A according to the second exemplary embodiment and a cross-sectional view taken along the line B-B in the plan view. The VCSEL 10A according to the second exemplary embodiment has a configuration that is substantially the same as the configuration of the VCSEL 10 according to the first exemplary embodiment except for a configuration of a second insulating film 118A. As illustrated in FIG. 3, the second insulating film 118A is formed as a ring-shaped pattern. An opening 118B having a circular shape is formed at the center of the second insulating film 118A. The first insulating film 112 is exposed through the opening 118B. The center of the opening 118B coincides with an optical axis, i.e., the center of the electrically conductive region 108B of the current confinement layer 108. The diameter of the opening 118B is set to be equal to or smaller than the diameter of the electrically conductive region 108B.

In the second exemplary embodiment, a reflectivity R2 of a region that is covered with the second insulating film 118A is set to be lower than a reflectivity R1 of a region that is not covered with the second insulating film 118A. Then, as in the first exemplary embodiment, the thickness h_{di} of the second insulating film 118A is selected so that the phase φₐᵢᵣ of laser light which emanates from the first insulating film 112 and which propagates through the air coincides with the phase φ_{di} of laser light which propagates through the second insulating film 118A and the phase difference between the phases is reduced. Preferably, the thickness of the second insulating film 118A is adjusted so that the thickness of the second insulating film 118A is in the range between about ±10% of the thickness h_{di} which is obtained using Equation 1. Accordingly, the phase difference between the phase of light that emanates from a region which is covered with the second insulating film 118A and the phase of light that emanates from a region which is not covered with the second insulating film 118A is reduced, whereby an FFP that is obtained using laser light generated by fundamental transverse-mode oscillation can be made to indicate a distribution close to a Gaussian distribution.

$${φ}_{air} = {sin}^{- 1} ( 2 π \frac{{h}_{di}}{λ} ) \\ {φ}_{di} = {sin}^{- 1} ( 2 π \frac{{h}_{di} {n}_{di}}{λ} ) \\ {φ}_{air} = {φ}_{di} \qquad ( 1 )$$

In Equation 1, h_{di} is a thickness of the dielectric, λ is an emission wavelength, n_{di} is a refractive index of the dielectric, φₐᵢᵣ is a phase of light that propagates through the air by a distance equal to the thickness h_{di}, and φ_{di} denotes a phase of light that propagates through the dielectric by a distance equal to the thickness h_{di}.

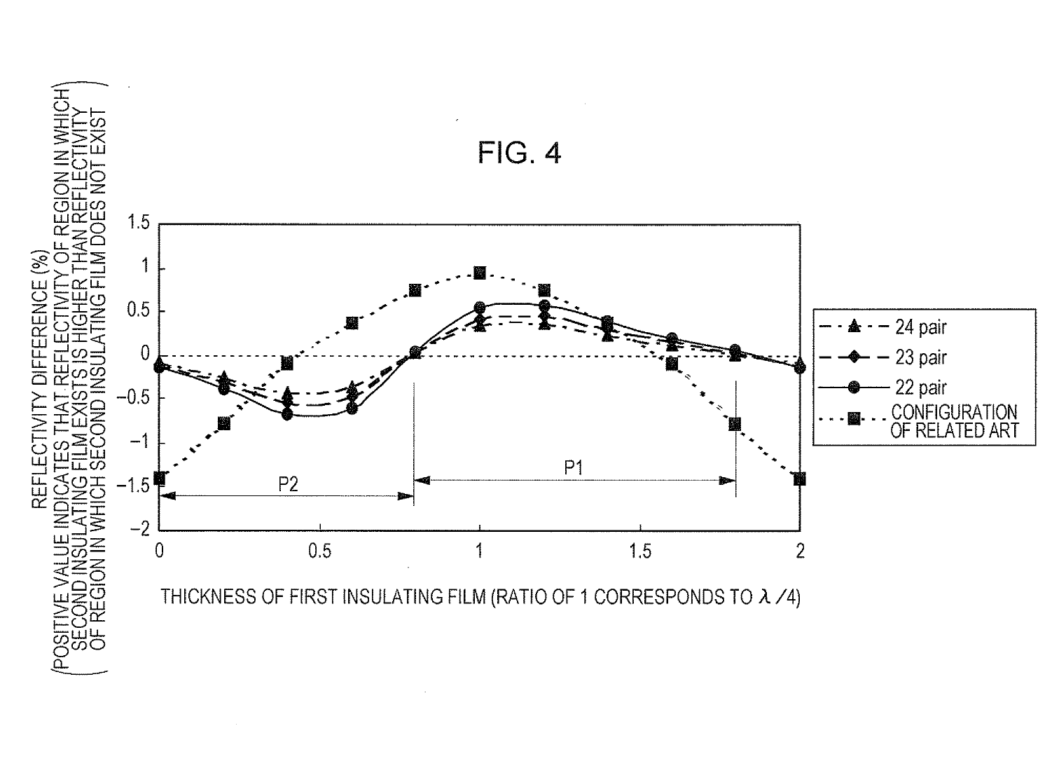

Next, reflectivity differences between reflectivities of regions that exist in light emitting apertures of VCSELs will be described. When the thickness of a first insulating film is changed, a thickness of a second insulating film is calculated so that the thickness of the second insulating film satisfies the equation φₐᵢᵣ=φ_{di}, and the relationships between the thickness of the first insulating film and the reflectivity difference between the reflectivity of a region in which the second insulating film exists and the reflectivity of a region in which the second insulating film does not exist are calculated. FIG. 4 is a graph illustrating the relationships. In the calculation, when the emission wavelength of a VCSEL is 780 nm and the refractive index n_{di} (=nᵣ₂) of the second insulating film is 1.92, the thickness h_{di} that satisfies the equation φₐᵢᵣ=φ_{di} is 848 nm. The horizontal axis indicates the thickness of the first insulating film. A case in which the thickness of the first insulating film 112 is λ/4 is represented by “1”, and thicknesses of the first insulating film are represented by ratios (“0” represents a case in which no first insulating film exists, and “2” represents a case in which the thickness of the first insulating film is λ/2). The vertical axis indicates the reflectivity difference. A positive value of the reflectivity difference indicates that the reflectivity of the region in which the second insulating film exists is higher than the reflectivity of the region in which the second insulating film does not exist. A negative value of the reflectivity difference indicates that the reflectivity of the region in which the second insulating film exists is lower than the reflectivity of the region in which the second insulating film does not exist. The curve with triangles shows the reflectivity difference in a case in which the upper DBR 106 has twenty-four pairs of a low-refractive-index layer having a high aluminum content and a high-refractive-index layer having a low aluminum content. The curve with diamonds shows the reflectivity difference in a case in which the upper DBR 106 has twenty-three pairs. The curve with circles shows the reflectivity difference in a case in which the upper DBR 106 has twenty-two pairs. The curve with squares shows the reflectivity difference in a VCSEL having a configuration of the related art in a case in which phase adjustment is not performed for the thickness of the second insulating film, i.e., in a case in which the thickness of a second insulating film is λ/4.

First, in the VCSEL having a configuration of the related art, when the thickness of the first insulating film is λ/4 (the thickness of the second insulating film is λ/4), the maximum of the reflectivity difference between a reflectivity of a region in which the second insulating film is formed and a reflectivity of a region in which the second insulating film is not formed in the light emitting aperture is about one. Here, the reflectivity of the region in which the second insulating film is formed becomes higher than the reflectivity of the region in which the second insulating film is not formed. Furthermore, when the thickness of a first insulating film is λ/2 and when a cover with the first insulating film is not provided, the reflectivity difference becomes about −1.5. In this case, the reflectivity of the region in which the second insulating film is formed becomes lower than the reflectivity of the region in which the second insulating film is not formed.

In the VCSEL having a configuration of the related art, the reflectivity of a region in the vicinity of the center of a light emitting aperture is relatively increased and the reflectivity of a region in the vicinity of the periphery is relatively decreased, whereby high-order transverse-mode oscillation can be reduced and fundamental transverse-mode oscillation can be generated. However, when a phase difference occurs between a phase φₐᵢᵣ of laser light that emanates from a region which is not covered with the second insulating film and that propagates through the air and a phase φ_{di} of laser light that emanates from a region which is covered with the second insulating film, non-uniformity in light intensity occurs due to interference. Because of this, an FFP does not indicate an ideal Gaussian distribution. When laser light having characteristics of such an FFP is used as a light source of an image forming apparatus, the quality of an image is reduced, and this is not desirable.

In the VCSEL according to the first exemplary embodiment, the reflectivity of the region that is covered with the second insulating film 118 increases, and the reflectivity of the region that is not covered with the second insulating film 118 decreases. In other words, the thickness of the first insulating film 112 is represented by a range P1 in which the reflectivity difference is positive in FIG. 4. The reflectivity difference depends on the number of pairs included in the upper DBR 106. However, when a value that is sufficient to reduce high-order transverse-mode oscillation and to enhance fundamental transverse-mode oscillation is considered, typically, it is preferable that the range of a thickness h of the first insulating film 112 be approximately represented by a relationship λ/4nᵣ₁<h≦3λ/8nᵣ₁ (where nᵣ₁ is the refractive index of the first insulating film 112).

Furthermore, in the VCSEL according to the second exemplary embodiment, the reflectivity of the region that is covered with the second insulating film 118A decreases, and the reflectivity of the region that is not covered with the second insulating film 118A increases. In this case, the thickness of the first insulating film 112 is represented by a range P2 in which the reflectivity difference is negative in FIG. 4. When a value that is sufficient to reduce high-order transverse-mode oscillation and to enhance fundamental transverse-mode oscillation is considered, it is preferable that the range of the thickness h of the first insulating film 112 be approximately represented by a relationship 0<h≦3λ/16nᵣ₁.

Each of the reflectivity differences that are obtained in the first and second exemplary embodiments remains approximately 0.5. The reflectivity difference is slightly lower than a reflectivity difference in the VCSEL having a configuration of the related art. However, if the reflectivity difference remains approximately 0.5, high-order transverse-mode oscillation can be reduced, and fundamental transverse-mode oscillation can be enhanced. Furthermore, as illustrated in FIG. 4, it is clear that the reflectivity decreases with decreasing number of pairs included in the upper DBR 106. Accordingly, it is desirable that the number of pairs included in the upper DBR 106 be appropriately selected so that the reflectivity of the entire upper DBR 106 and the reflectivity difference in the light emitting aperture 110A are optimized.

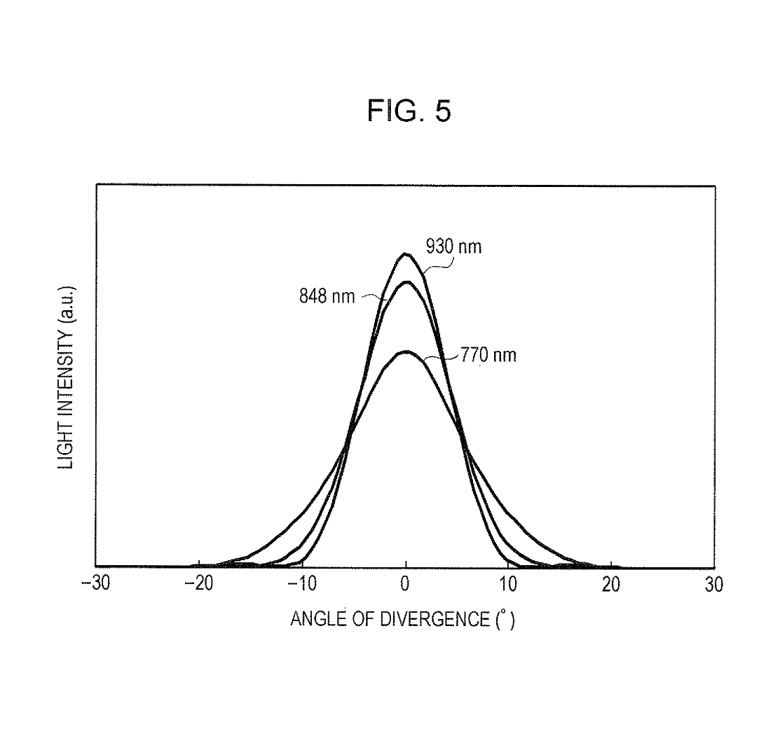

FIG. 5 illustrates an FFP profile in a case in which the thickness of the second insulating film is changed. The horizontal axis indicates an angle of divergence, and the vertical axis indicates a light intensity. As described above, in a case in which the thickness h_{di} of the second insulating film satisfies Equation 1, the thickness h_{di} is 848 nm. An FFP in this case indicates fundamental transverse-mode oscillation and a Gaussian distribution. In a case in which the thickness of the second insulating film is set to be 930 nm that is only 10% larger than the thickness h_{di}, a phase difference occurs between the phase φₐᵢᵣ and the phase φ_{di} to some degree. As illustrated in FIG. 5, an FFP in this case indicates a distribution almost close to a Gaussian distribution although the distribution is a unimodal distribution in which the angle of divergence decreases. Similarly, in a case in which the thickness of the second insulating film is set to be 770 nm that is only 10% smaller than the thickness h_{di}, an FFP in this case indicates a distribution almost close to a Gaussian distribution although the distribution is a unimodal distribution in which the angle of divergence increases to some degree. Accordingly, if the thickness of the second insulating film is in the range of about ±10% of the thickness h_{di} that satisfies the equation φₐᵢᵣ=φ_{di} included in Equation 1, fundamental transverse-mode oscillation can be generated, and an FFP that is obtained using laser light which is emitted by generating the fundamental transverse-mode oscillation can indicate a distribution close to a Gaussian distribution.

As described above, when each of the VCSELs according to the first and second exemplary embodiments is applied as a light source of an image forming apparatus or the like, an FFP can be made to indicate a Gaussian distribution. Accordingly, the quality of an image can be improved, compared with a quality of an image that is obtained using the VCSEL having a configuration of the related art. Furthermore, in the VCSEL according to the present exemplary embodiment, the diameter of the electrically conductive region 108B, i.e., an oxidation aperture diameter, can be set to be in a range (for example, about five micrometers) from which the diameter is selected so that high-order transverse-mode oscillation can be generated. Accordingly, the optical power of laser light can be increased. Simultaneously, increase of the oxidation aperture diameter facilitates control of oxidation, and leads to an increase in the yield of the VCSEL.

In order to increase the reflectivity difference between the reflectivity of a portion that is covered with the second insulating film and the reflectivity of a portion that is not covered with the second insulating film, it is preferable that materials for the first insulating film and the second insulating film be selected so that the difference between the refractive index of the first insulating film and the refractive index of the second insulating film is increased.

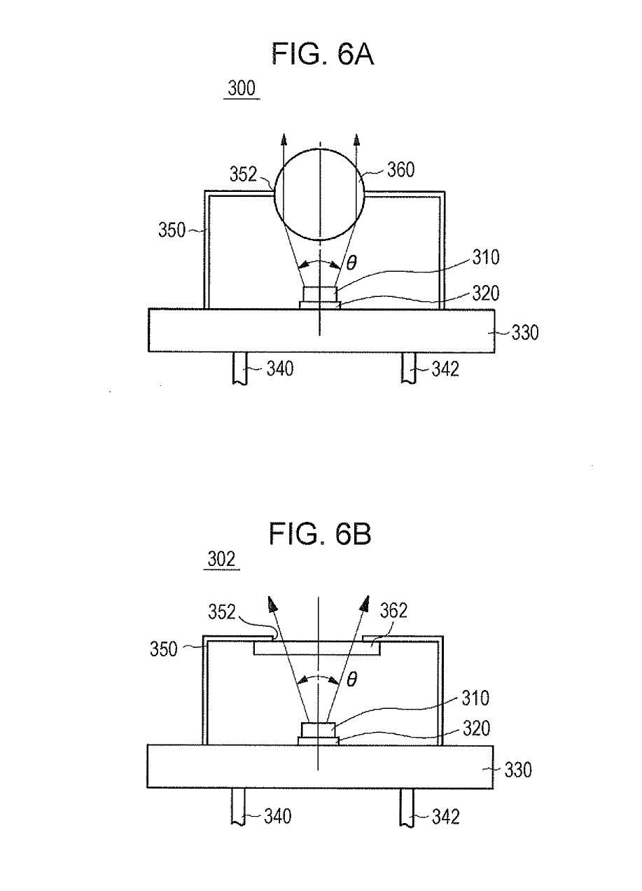

Next, a VCSEL device, an optical information processing apparatus, and an optical transmission apparatus, each of which utilizes the VCSEL according to the present exemplary embodiment, will be described with reference to FIGS. 6A and 6B and FIGS. 7 and 8. FIG. 6A is a schematic cross-sectional view illustrating a configuration of a VCSEL device in which the VCSEL and an optical member are implemented (packaged). A VCSEL device 300 fixes a chip 310, in which the VCSEL is formed, on a disk-shaped metallic stem 330 via an electrically conductive adhesive 320. Leads 340 and 342 that are electrically conductive are inserted into through holes (not illustrated) that are formed in the stem 330. The lead 340, which is one of the two leads, is electrically connected to an n-side electrode of the VCSEL, and the lead 342, which is the other lead, is electrically connected to a p-side electrode of the VCSEL.

A rectangular hollow cap 350 is fixed on the stem 330 including the chip 310. A ball lens 360 that is an optical member is fixed in an opening 352 that is provided at the center of the cap 350. The optical axis of the ball lens 360 is positioned so as to almost coincide with the center of the chip 310. When a forward voltage is applied between the leads 340 and 342, laser light is emitted from the chip 310 in the vertical direction. The distance between the chip 310 and the ball lens 360 is adjusted so that the ball lens 360 is included in a region corresponding to an angle θ of divergence of the laser light emitted from the chip 310. Furthermore, a light receiving element or a temperature sensor for monitoring a light emission state of the VCSEL may be included in the cap 350.

FIG. 6B is a diagram illustrating a configuration of another VCSEL device. A VCSEL device 302 illustrated in FIG. 6B fixes a plate glass 362 in the opening 352 that is provided at the center of the cap 350, instead of using the ball lens 360. The center of the plate glass 362 is positioned so as to almost coincide with the center of the chip 310. The distance between the chip 310 and the plate glass 362 is adjusted so that the diameter of an opening of the plate glass 362 is equal to or larger than a distance corresponding to the angle θ of divergence of the laser light emitted from the chip 310.

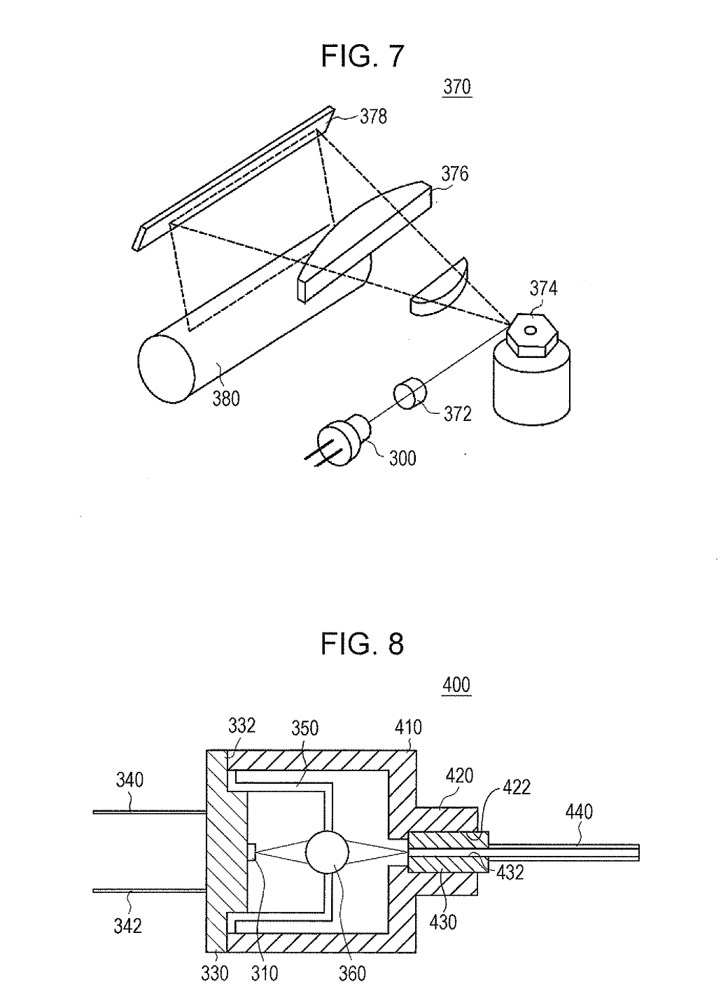

FIG. 7 is a diagram illustrating an example in which the VCSEL is applied as a light source of an optical information processing apparatus. An optical information processing apparatus 370 includes a collimator lens 372, a polygon mirror 374, an fθ lens 376, a reflection mirror 378, and a photoconductor drum (recording medium) 380. Laser light emitted from the VCSEL device 300 or 302 in which the VCSEL is implemented as illustrated in FIG. 6A or 6B enters the collimator lens 372. The polygon mirror 374 rotates at a fixed speed, and reflects, at a fixed angle of divergence, a pencil of light rays supplied from the collimator lens 372. Laser light emitted from the polygon mirror 374 enters the fθ lens 376, and the fθ lens 376 irradiates the reflection mirror 378 with the laser light. The reflection mirror 378 has a line shape. The photoconductor drum (recording medium) 380 forms a latent image on the basis of light reflected by the reflection mirror 378. As described above, the VCSEL can be utilized as a light source of an optical information processing apparatus, such as a copier or a printer including an optical system that gathers laser light, which is emitted by the VCSEL, on a photoconductor drum, and a mechanism that scans the gathered laser light on the photoconductor drum.

FIG. 8 is a schematic cross-sectional view illustrating a configuration in a case in which the VCSEL device illustrated in FIG. 6A is applied in an optical transmission apparatus. An optical transmission apparatus 400 includes a housing 410, a sleeve 420, a ferrule 430, and an optical fiber 440. The housing 410 is fixed in the stem 330, and has a cylindrical shape. The sleeve 420 is formed on the end face of the housing 410 so that the sleeve 420 and the housing 410 are formed as one piece. The ferrule 430 is held in an opening 422 of the sleeve 420. The optical fiber 440 is held by the ferrule 430. An end portion of the housing 410 is fixed to a flange 332 that is formed in the stem 330 in the circumferential direction. The ferrule 430 is accurately positioned in the opening 422 of the sleeve 420. The optical axis of the optical fiber 440 is made to match with the optical axis of the ball lens 360. A core wire of the optical fiber 440 is held in a through hole 432 of the ferrule 430.

Laser light emitted from the surface of the chip 310 is gathered by the ball lens 360. The gathered light enters the core wire of the optical fiber 440, and transmitted. Although the ball lens 360 is used in the above-described example, a lens other than a ball lens, such as a double-convex lens or a plano-convex lens, may be used. Furthermore, the optical transmission apparatus 400 may include a driving circuit for applying electric signals to the leads 340 and 342. Moreover, the optical transmission apparatus 400 may include a reception function for receiving a light signal via the optical fiber 440.

As described above, the exemplary embodiments of the present invention are described. However, the present invention is not limited to a specific exemplary embodiment. Various changes and modifications may be made without departing from the gist of the present invention described in claims.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A vertical cavity surface emitting laser comprising:
a substrate;
a first semiconductor multilayer film reflector of a first conductivity type, the first semiconductor multilayer film reflector being formed on the substrate;
an active region that is formed on the first semiconductor multilayer film reflector;
a second semiconductor multilayer film reflector of a second conductivity type that is a conductivity type different from the first conductivity type, the second semiconductor multilayer film reflector being formed on the active region;
an electrode which is formed on the second semiconductor multilayer film reflector, and in which a light emitting aperture from which light is emitted is formed;
a first substance that is composed of a material which light having an emission wavelength is able to pass through, and that is formed in the light emitting aperture of the electrode; and
a second substance that is composed of a dielectric which the light having the emission wavelength is able to pass through, and that is formed on the first substance so as to cover one portion of the first substance,
wherein a thickness of the second substance is in a range between about ±10% of h_{di} that is obtained using Equation 1:
$${φ}_{air} = {sin}^{- 1} ( 2 π \frac{{h}_{di}}{λ} ) \\ {φ}_{di} = {sin}^{- 1} ( 2 π \frac{{h}_{di} {n}_{di}}{λ} ) \\ {φ}_{air} = {φ}_{di} \qquad ( 1 )$$
where h_{di} is a thickness of the dielectric, λ is an emission wavelength, n_{di} is a refractive index of the dielectric, φₐᵢᵣ is a phase of light that propagates through the air by a distance equal to the thickness h_{di}, and φ_{di} is a phase of light that propagates through the dielectric by a distance equal to the thickness h_{di}, and
wherein a reflectivity of a portion that is covered with the second substance is higher than a reflectivity of a portion that is not covered with the second substance.

2. The vertical cavity surface emitting laser according to claim 1, wherein the thickness of the second substance is h_{di} that is obtained using Equation 1.

3. The vertical cavity surface emitting laser according to claim 1, wherein a range of a thickness h of the first substance is approximately represented by a relationship λ/4nᵣ₁ nλ/2nᵣ₁<h≦3λ/8nᵣ₁+nλ/2nᵣ₁ where n is zero or a positive integer and nᵣ₁ is a refractive index of the first substance.

4. The vertical cavity surface emitting laser according to claim 1, further comprising a current confinement layer which is formed on the substrate and in which an insulating region and an electrically conductive region are formed, the insulating region being formed around the electrically conductive region, the electrically conductive region having a circular shape,
wherein the light emitting aperture has a circular shape that is formed at a position corresponding to the electrically conductive region, and
wherein the second substance is formed in a circular shape that has a diameter which is smaller than a diameter of the light emitting aperture and which is equal to or smaller than a diameter of the electrically conductive region.

5. A vertical cavity surface emitting laser comprising:
a substrate;
a first semiconductor multilayer film reflector of a first conductivity type, the first semiconductor multilayer film reflector being formed on the substrate;
an active region that is formed on the first semiconductor multilayer film reflector;
a second semiconductor multilayer film reflector of a second conductivity type that is a conductivity type different from the first conductivity type, the second semiconductor multilayer film reflector being formed on the active region;
an electrode which is formed on the second semiconductor multilayer film reflector, and in which a light emitting aperture from which light is emitted is formed;
a first substance that is composed of a material which light having an emission wavelength is able to pass through, and that is formed in the light emitting aperture of the electrode; and
a second substance that is composed of a dielectric which the light having the emission wavelength is able to pass through, and that is formed on the first substance so as to cover one portion of the first substance,
wherein a thickness of the second substance is in a range between about ±10% of h_{di} that is obtained using Equation 1:
$${φ}_{air} = {sin}^{- 1} ( 2 π \frac{{h}_{di}}{λ} ) \\ {φ}_{di} = {sin}^{- 1} ( 2 π \frac{{h}_{di} {n}_{di}}{λ} ) \\ {φ}_{air} = {φ}_{di} \qquad ( 1 )$$
where h_{di} is a thickness of the dielectric, λ is an emission wavelength, n_{di} is a refractive index of the dielectric, φₐᵢᵣ is a phase of light that propagates through the air by a distance equal to the thickness h_{di}, and φ_{di} is a phase of light that propagates through the dielectric by a distance equal to the thickness h_{di}, and
wherein a reflectivity of a portion that is covered with the second substance is lower than a reflectivity of a portion that is not covered with the second substance.

6. The vertical cavity surface emitting laser according to claim 5, wherein the thickness of the second substance is h_{di} that is obtained using Equation 1.

7. The vertical cavity surface emitting laser according to claim 5, wherein a range of a thickness h of the first substance is approximately represented by a relationship nλ/2nᵣ₁<h≦3λ/16nᵣ₁+nλ/2nᵣ₁ where n is zero or a positive integer and nᵣ₁ is a refractive index of the first substance.

8. The vertical cavity surface emitting laser according to claim 5, further comprising a current confinement layer which is formed on the substrate and in which an insulating region and an electrically conductive region are formed, the insulating region being formed around the electrically conductive region, the electrically conductive region having a circular shape,
wherein the light emitting aperture has a circular shape that is formed at a position corresponding to the electrically conductive region, and
wherein the second substance has a ring shape in which an opening having a circular shape is formed at a center, and a diameter of the opening of the second substance is smaller than a diameter of the light emitting aperture and is equal to or smaller than a diameter of the electrically conductive region.

9. The vertical cavity surface emitting laser according to claim 4, wherein the diameter of the electrically conductive region is about five micrometers or larger.

10. The vertical cavity surface emitting laser according to claim 4,
wherein a columnar structure extending from the second semiconductor multilayer film reflector to the first semiconductor multilayer film reflector is formed, and
wherein the insulating region of the current confinement layer includes an oxidized region that is oxidized from a side wall of the columnar structure.

11. The vertical cavity surface emitting laser according to claim 8, wherein the diameter of the electrically conductive region is about five micrometers or larger.

12. The vertical cavity surface emitting laser according to claim 8,
wherein a columnar structure extending from the second semiconductor multilayer film reflector to the first semiconductor multilayer film reflector is formed, and
wherein the insulating region of the current confinement layer includes an oxidized region that is oxidized from a side wall of the columnar structure.

13. A vertical-cavity-surface-emitting-laser device comprising:
the vertical cavity surface emitting laser according to claim 1; and
an optical member that light emitted from the vertical cavity surface emitting laser enters.

14. An optical transmission apparatus comprising;
the vertical-cavity-surface-emitting-laser device according to claim 13; and
a transmission unit that transmits, via an optical medium, laser light emitted from the vertical-cavity-surface-emitting-laser device.

15. An information processing apparatus comprising:
the vertical cavity surface emitting laser according to claim 1;
a light gathering unit that gathers, onto a recording medium, laser light which is emitted from the vertical cavity surface emitting laser; and
a mechanism that scans the laser light, which has been gathered by the light gathering unit, on the recording medium.

16. A vertical-cavity-surface-emitting-laser device comprising:
the vertical cavity surface emitting laser according to claim 5; and
an optical member that light emitted from the vertical cavity surface emitting laser enters.

17. An optical transmission apparatus comprising:
the vertical-cavity-surface-emitting-laser device according to claim 16; and
a transmission unit that transmits, via an optical medium, laser light emitted from the vertical-cavity-surface-emitting-laser device.

18. An information processing apparatus comprising:
the vertical cavity surface emitting laser according to claim 5;
a light gathering unit that gathers, onto a recording medium, laser light which is emitted from the vertical cavity surface emitting laser; and
a mechanism that scans the laser light, which has been gathered by the light gathering unit, on the recording medium.
